(19) United States
(12) Patent Application Publication
(10) Pub. No.: US 2013/0326295 A1
(43) Pub. Date: Dec. 5, 2013

(54) SEMICONDUCTOR MEMORY DEVICE INCLUDING SELF-CONTAINED TEST UNIT AND TEST METHOD THEREOF

(71) Applicants: Tae Ho JEON, Icheon-si Gyeonggi-do (KR); Junw Seop JUNG, Icheon-si Gyeonggi-do (KR); Sung Hyun JUNG, Icheon-si Gyeonggi-do (KR)

(72) Inventors: Tae Ho JEON, Icheon-si Gyeonggi-do (KR); Junw Seop JUNG, Icheon-si Gyeonggi-do (KR); Sung Hyun JUNG, Icheon-si Gyeonggi-do (KR)

(73) Assignee: SK Hynix Inc., Icheon-si Gyeonggi-do (KR)

(21) Appl. No.: 13/620,419

(22) Filed: Sep. 14, 2012

(30) Foreign Application Priority Data
May 31, 2012 (KR) 10-2012-0058231

(51) Int. Cl. G11C 29/10

(52) U.S. Cl. 714/719; 714/E11.159

(57) ABSTRACT

A semiconductor memory device is configured to internally perform a test operation utilizing a random data pattern. The semiconductor memory device includes a random data pattern test unit that operates under control of on-board control logic that also manages normal operation of the semiconductor memory device. The control logic controls test operation of the semiconductor memory device in response to simple commands received from an external device. Therefore, the test time may be reduced more than when a test is entirely controlled by an external device. Furthermore, since the external device does not need to manage the random data pattern, the test cost may be reduced more than when a test is performed under control of the external device.

### CROSS-REFERENCES TO RELATED APPLICATION

The present application claims priority under 35 U.S.C. §119(a) to Korean application number 10-2012-0058231, filed on May 31, 2012, in the Korean Intellectual Property Office, which is incorporated herein by reference in its entirety.

### BACKGROUND

1. Technical Field

The present invention relates generally to a semiconductor memory device, and more particularly, to a semiconductor memory device including a test unit and a test method thereof.

2. Related Art

In general, a semiconductor memory device is classified into a volatile memory device and a nonvolatile memory device. The volatile memory device loses data stored therein when power is cut off, but the nonvolatile memory device maintains data stored therein when power is cut off. The nonvolatile memory device includes various types of memory cell transistors. The nonvolatile memory device may be divided into a flash memory device, a ferroelectric RAM (FRAM), a magnetic RAM (MRAM), a phase change RAM (PRAM) and the like, depending on the structures of the memory cell transistors.

Among the nonvolatile memory device, the flash memory device is roughly divided into a NOR flash memory device and a NAND flash memory device, depending on a connection state between memory cells and bit lines. The NOR flash memory device has a structure in which two or more memory cell transistors are connected in parallel to one bit line. Therefore, the NOR flash memory device has an excellent random access time characteristic. On the other hand, the NAND flash memory device has a structure in which two or more memory cell transistors are connected in series to one bit line. Such a structure is referred to as a cell string structure, and one bit line contact is required per cell string. Therefore, the NAND flash memory device has an excellent characteristic in terms of integration degree.

Memory cells of the flash memory device are divided into on cells and off cells depending on a threshold voltage distribution. The on cell is an erased cell, and the off cell is a programmed cell. The threshold voltage of the programmed memory cell may be changed by various factors. For example, the threshold voltage of the programmed memory cell may be changed by program disturbance or coupling between adjacent memory cells. More specifically, the change in the threshold voltage of the programmed memory cell will be described as follows.

For example, according to data programmed into a selected memory cell during a program operation, program states (that is, threshold voltage distribution) of adjacent memory cells may be changed. Furthermore, during a read operation, a cell current flowing through a selected memory cell may be changed according to program states (that is, threshold voltage distribution) of adjacent memory cells. In other words, the threshold voltage of a memory cell may be changed according to data to be programmed into a selected memory cell or a data pattern indicating program states of adjacent memory cells.

As described above, a memory cell may be more influenced or less influenced by program disturbance or coupling, depending on a specific data pattern. Therefore, there is a demand for devices and methods for testing whether or not a semiconductor memory device performs a stable operation with respect to various data patterns.

### SUMMARY

A semiconductor memory device including a test unit and a test method thereof are described herein.

In an embodiment of the present invention, a test method of a semiconductor memory device includes the steps of: generating a first random data pattern inside the semiconductor memory device and programming the first random data pattern into the semiconductor memory device; and generating a second random data pattern inside the semiconductor memory device and comparing the second random data pattern to a data pattern read from memory cells of the semiconductor memory device.

In an embodiment of the present invention, a test method of a semiconductor memory device includes the steps of: generating a random data pattern inside the semiconductor memory device in response to a test command provided from an external device; performing a test using the random data pattern; and outputting a test result to the external device.

In an embodiment of the present invention, a semiconductor memory device includes: memory cells; a random data pattern test unit configured to generate a random data pattern; and a data read/write circuit configured to program the random data pattern provided from the random data pattern test unit into the memory cells during a test operation.

### BRIEF DESCRIPTION OF THE DRAWINGS

Features, aspects, and embodiments are described in conjunction with the attached drawings, in which:

FIG. 1 is a block diagram illustrating a semiconductor memory device according to an embodiment of the present invention;

FIG. 2 is a flow chart showing a test method of the semiconductor memory device according to an embodiment of the present invention;

FIG. 3 is a flow chart showing a test program method of the test method of FIG. 2 in more detail;

FIG. 4 is a block diagram of a semiconductor memory device according to an embodiment of the present invention;

FIG. 5 is a timing diagram illustrating the test program method of FIG. 3;

FIG. 6 is a flow chart showing a first test read method of the test method of FIG. 2 in more detail;

FIG. 7 is a block diagram of a semiconductor memory device according to an embodiment of the present invention;

FIG. 8 is a timing diagram illustrating the first test read method of FIG. 6;

FIG. 9 is a flow chart showing a second test read method of the test method of FIG. 2 in more detail;

FIG. 10 is a block diagram of a semiconductor memory device according to an embodiment of the present invention;

FIG. 11 is a timing diagram illustrating the second test read method of FIG. 9;

FIG. 12 is a flow chart showing a test method of a semiconductor memory device according to another embodiment of the present invention; and

FIG. 13 is a timing diagram illustrating a test method of a semiconductor memory device according to yet another embodiment of the present invention.

### DETAILED DESCRIPTION

Hereinafter, a semiconductor memory device including a test unit and a test method thereof according to the present invention will be described below with reference to the accompanying drawings through illustrative embodiments.

Embodiments of the present invention will be described below in more detail with reference to the accompanying drawings. The present invention may, however, be embodied in different forms and should not be construed as limited to the embodiments set forth herein.

The drawings are not necessarily to scale and in some instances, proportions may have been exaggerated in order to clearly illustrate features of the embodiments. In this specification, specific terms have been used. The terms are used to describe the present invention, and are not used to qualify the sense or limit the scope of the present invention.

In this specification, ‘and/or’ represents that one or more of components arranged before and after ‘and/or’ is included. Furthermore, ‘connected/coupled’ represents that one component is directly coupled to another component or indirectly coupled through another component. In this specification, a singular form may include a plural form as long as it is not specifically mentioned in a sentence. Furthermore, ‘include/comprise’ or ‘including/comprising’ used in the specification represents that one or more components, steps, operations, and elements exists or are added.

Hereafter, embodiments of the present invention will be described in detail with reference to the accompanying drawings.

In the following descriptions, a NAND flash memory device, which is a kind of nonvolatile memory device, is used as one example for describing features and functions of the present invention. However, the features and functions of the present invention, which will be described below, are not limited to a specific type of semiconductor memory device. That is, a test method of a semiconductor memory device, which will be described below, may be applied to both a volatile memory device and a nonvolatile memory device.

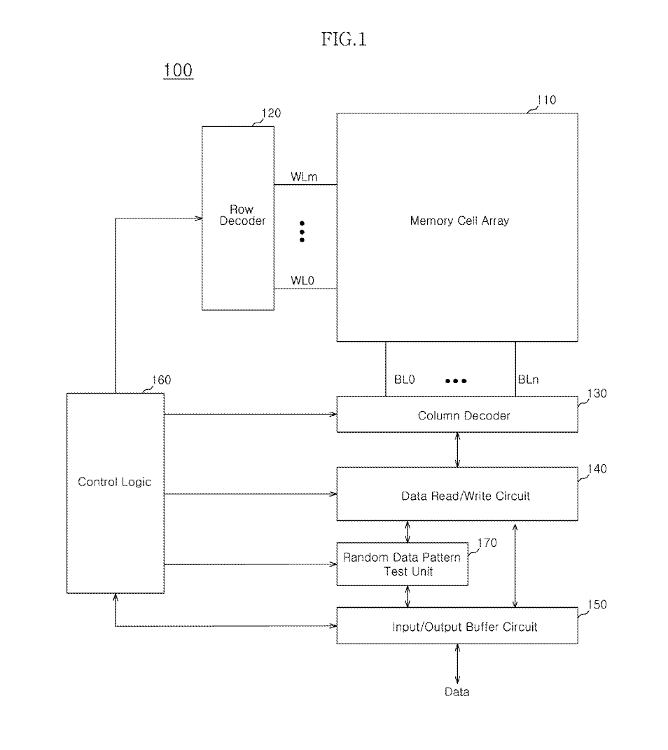

FIG. 1 is a block diagram illustrating a semiconductor memory device according to an embodiment of the present invention. Referring to FIG. 1, the semiconductor memory device 100 includes a memory cell array 110, a row decoder 120, a column decoder 130, a data read/write circuit 140, an input/output buffer circuit 150, a control logic 160, and a random data pattern test unit 170.

The memory cell array 110 includes a plurality of memory cells arranged at the respective intersections between bit lines BL0 to BLn and word lines WL0 to WLn. Each of the memory cells may store one bit data. Such a memory cell is referred to as a single level cell (SLC). The SLC is programmed in such a manner as to have a threshold voltage corresponding to an erase state and one program state. As another example, each of the memory cells may store two or more-bit data. Such a memory cell is referred to as an MLC. The MLC is programmed in such a manner as to have a threshold voltage corresponding to an erase state and any one of a plurality of program states, according to the multi-bit data. The memory cell array 110 may be implemented to have a single-layer array structure (referred to as a two-dimensional array structure) or a multilayer array structure (referred to as a three-dimensional array structure).

The row decoder 120 operates according to the control of the control logic 160. The row decoder 120 is configured to perform a selecting operation and a driving operation for rows of the memory cell array 110 in response to an address. For example, the row decoder 120 is configured to transfer various word line voltages provided from a voltage generator (not illustrated) to a selected word line and unselected word lines.

The column decoder 130 operates according to the control of the control logic 160. The column decoder 130 is configured to select bit lines BL0 to BLn (or data read/write circuits) in response to an address.

The data read/write circuit 140 operates according to the control of the control logic 160. The data read/write circuit 140 is configured to operate as a write driver or sense amplifier depending on an operation mode. Furthermore, the data read/write circuit 140 is configured to compare a random data pattern to data read from the memory cell array 110 during a test read operation. The test read operation of the data read/write circuit 140 will be described below in detail.

The input/output buffer circuit 150 is configured to receive data from an external device (for example, a memory controller, a memory interface, a host device or the like) or output data to the external device. Here, the data may include not only data programmed into the memory cell array 110 or read from the memory cell array 110, but also control signals such as command and address. The input/output buffer circuit 150 may include a data latch circuit and an output driving circuit, in order to input and output data.

The control logic 160 is configured to control overall operations of the semiconductor memory device 100 in response to a control signal provided from the external device. For example, the control logic 160 may control a read, program (or write), or erase operation of the semiconductor memory device 100. As another example, the control logic 160 is configured to control a test operation of the semiconductor memory device 100 in response to test commands (for example, a test program command, a test read command and the like). This means that the test operation of the semiconductor memory device 100 is not performed directly by the external device, but instead performed inside the semiconductor memory device 100.

The random data pattern test unit 170 operates according to the control of the control logic 160. The random data pattern test unit 170 is configured to generate a random data pattern during a test program operation. The random data pattern test unit 170 is configured to compare the generated random data pattern to the data read from the memory cell array 110 during a test read operation. The configuration and operation of the random data pattern test unit 170 will be described below in detail.

According to an embodiment of the present invention, the semiconductor memory device 100 is configured to internally perform a test operation for a random data pattern. Therefore, the test time may be reduced more than when a test is performed under control of the external device. Furthermore, since the external device does not need to manage a random data pattern, the test cost may be reduced more than when a test is performed under control of the external device.

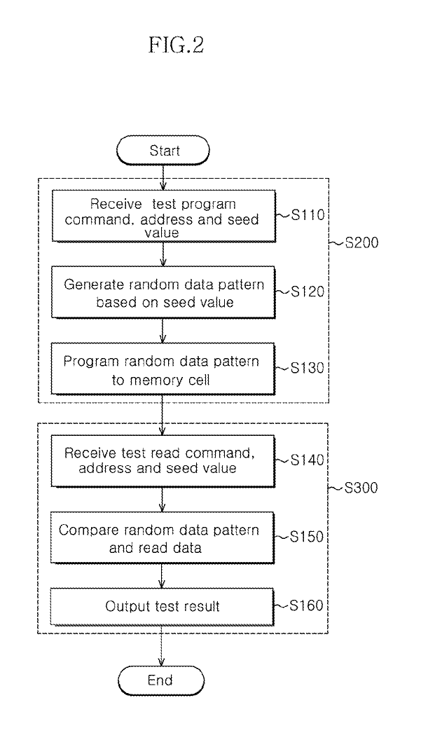

FIG. 2 is a flow chart showing a test method of the semiconductor memory device according to an embodiment of the present invention. Referring to FIG. 2, the test method of the semiconductor memory device 100 of FIG. 1 is divided into a test program method S200 for programming a random data pattern into a memory cell and a test read method S300 for detecting a test result by comparing the random data pattern to data programmed in the memory cell.

The test program method S200 for programming a random data pattern includes the steps of generating a random data pattern inside the semiconductor memory device 100 and programming the generated random data pattern into a memory cell. The test program method S200 will be described in more detail as follows.

At step S110, the semiconductor memory device 100 receives a test program command, an address, and a seed value from an external device, for example, a test device. The semiconductor memory device 100 may perform a test program operation in response to the test program command. At step S120, the semiconductor memory device 100 generates a random data pattern based on the received seed value. This means that data to be used for the test program operation are not provided from the external device, for example, the test device. At step S130, the semiconductor memory device 100 programs the internally-generated random data pattern into a memory cell.

In order to determine whether or not the random data pattern was normally programmed into the memory cell, or whether random data programmed in a memory cell was changed by a physical failure, for example, program disturbance or coupling effect, the test read method S300 is performed. The test read method S300 for comparing the random data pattern to the data programmed in the memory cell includes the steps of generating a random data pattern inside the semiconductor memory device 100 and comparing the generated random data pattern to data read from a memory cell. The test read method S300 will be described in more detail as follows.

At step S140, the semiconductor memory device 100 receives a test read command, an address, and a seed value from an external device, for example, a test device. The semiconductor memory device 100 may perform a test read operation in response to the test read command. At step S150, the semiconductor memory device 100 compares a random data pattern generated based on the received seed value to data read from a memory cell. At step S160, the semiconductor memory device 100 outputs a test result generated according to the comparison result to the external device, for example, the test device.

Through this series of operations, it is possible to test whether or not the random data pattern is normally programmed into the semiconductor memory device 100, or whether or not the semiconductor memory device 100 stably operates with respect to the random data pattern.

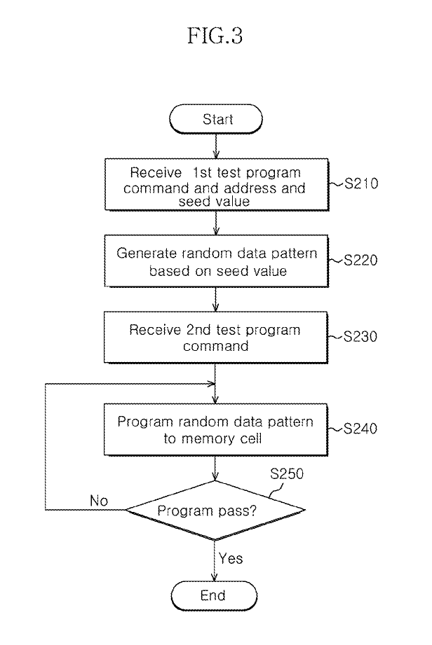

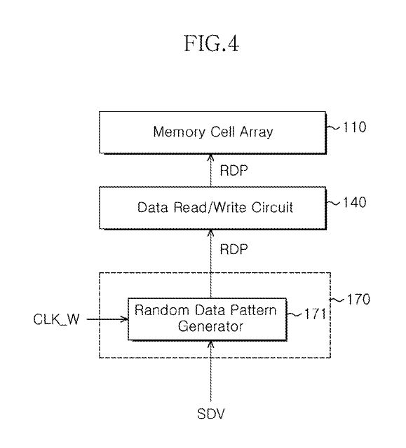

FIG. 3 is a flow chart showing the test program method of the test method of FIG. 2 in more detail. FIG. 4 is a block diagram of a semiconductor memory device according to an embodiment of the present invention. Here, referring to FIGS. 3 and 4, the test program method according to an embodiment of the present invention will be described in detail.

At step S210, the semiconductor memory device 100 of FIG. 1 receives a first program command, an address, and a seed value SDV from an external device, for example, a test device. The received seed value SDV is provided to a random data pattern generator 171 of the random data pattern test unit 170.

At step S220, the random data pattern generator 171 generates a random data pattern RDP based on the seed value SDV. The random data pattern generator 171 may generate the random data pattern RDP in response to a clock signal CLK_W provided from the control logic 160 of FIG. 1. The generated random data pattern RDP is provided to the data read/write circuit 140. For example, the random data pattern generator 171 may include a random data generation circuit such as a linear feedback shift register (LFSR).

At step S230, the semiconductor memory device 100 receives a second test program command from the external device, for example, the test device. At step S240, when the second test program command is received, the random data pattern RDP temporarily-stored in the data read/write circuit 140 is programmed into memory cells of the memory cell array 110.

At step S250, whether or not the memory cells are programmed to have states required is determined. When the memory cells are not programmed to have the states required, the program operation may be repeated by a predetermined number. That is, a program loop including the steps S240 and S250 is repeated by a predetermined number, in order to perform the program operation. On the other hand, when the memory cells are programmed to have the states required, the program operation is ended.

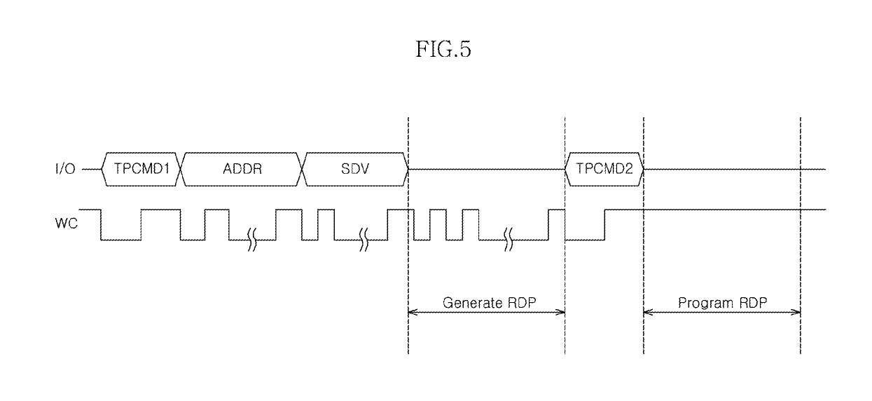

FIG. 5 is a timing diagram illustrating the test program method of FIG. 3. FIG. 5 depicts a timing diagram of input/output data and a control signal based on the flow chart of the test program method.

The first test program command TPCMD1, the address ADDR, and the seed value SDV are provided to the semiconductor memory device in synchronization with a write control signal WC. The seed value SDV may have a different size, depending on the complexity of the random data pattern RDP.

The size of the random data pattern RDP is controlled by the write control signal WC. That is, the number of random data patterns RDP to be generated corresponds to the toggling number of the write control signal WC. The number of random data patterns RDP to be is generated corresponds to the number of memory cells of the semiconductor memory device 100, which may be programmed at the same time. Meanwhile, the clock signal CLK_W provided to the random data pattern generator 171 of FIG. 4 to generate the random data pattern RDP may be generated based on the write control signal WC.

When the second test program command TPCMD2 is provided, the generated random data pattern RDP is programmed into memory cells. That is, after the second test program command TPCMD2 is provided, the actual program operation to apply a program current or voltage is performed after the second test program command TPCMD2 is provided.

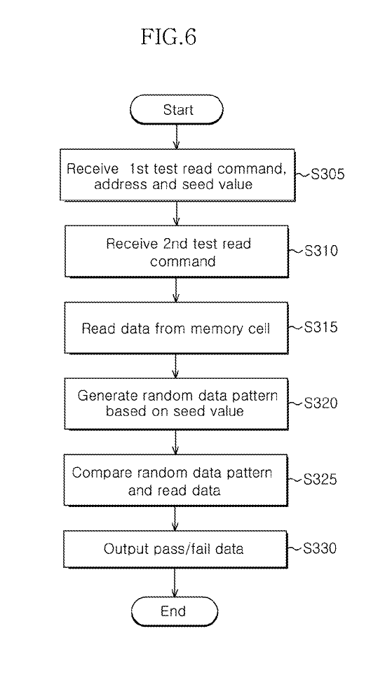

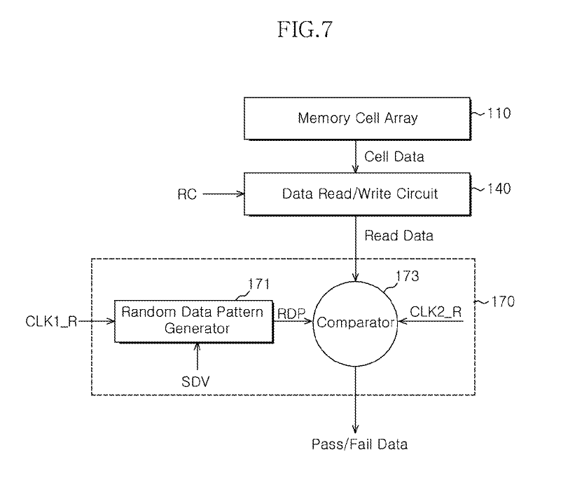

FIG. 6 is a flow chart showing a first test read method of the test method of FIG. 2 in more detail. FIG. 7 is a block diagram of the semiconductor memory device according to an embodiment of the present invention. Hereafter, referring to FIGS. 6 and 7, the first test read method according to an embodiment of the present invention will be described in detail.

At step S305, the semiconductor memory device 100 of FIG. 1 receives a first test read command, an address, and a seed value SDV from an external device, for example, a test device. The received seed value SDV is provided to the random data pattern generator 171 of the random data pattern test unit 170.

At step S310, the semiconductor memory device 100 receives a second test read command from the external device, for example, the test device.

At step S315, when the second test read command is received, the data read/write circuit 140 reads cell data from memory cells of the memory cell array 110. That is, the data read/write circuit 140 reads the data programmed in the memory cells. The read data may be temporarily stored in the data read/write circuit 140.

At step S320, when the second test read command is received, the random data pattern generator 171 generates a random data pattern RDP based on the seed value SDV. The random data pattern generator 171 may generate the random data pattern RDP in response to a clock signal CLK1_R provided from the control logic 160 of FIG. 1. For this reason, the clock signal CLK1_R may be generated based on a read control signal RC. Therefore, the number of generated random data patterns RDP corresponds to the toggling number of the read control signal RC. The generated random data pattern RDP is provided to a comparator 173.

For example, the random data pattern generator 171 may include a random data generation circuit such as a linear feedback shift register (LFSR).

The random data pattern generation operation of the random data pattern generator 171 may be performed while or after the data read/write circuit 140 senses cell data. That is, the steps S315 and S320 may be performed simultaneously or sequentially.

At step S325, the comparator 173 compares the read data provided by the data read/write circuit 140 to the random data pattern RDP provided from the random data pattern generator 171. The comparator 173 may include a logic circuit configured to perform a logic operation. For example, the comparator 173 may include a circuit configured to perform an XOR operation on the read data and the random data pattern RDP.

At step S330, the comparator 173 outputs test pass/fail data in response to a clock signal CLK2_R provided from the control logic 160. The clock signal CLK2_R may be generated based on the read control signal RC. The comparator 173 may output the test pass data when the read data and the random data pattern RDP have the same value. Furthermore, the comparator 173 may output the test fail data when the read data and the random data pattern RDP have different values. That is, the comparator 173 may output test pass/fail information of the respective memory cells in response to the read control signal RC.

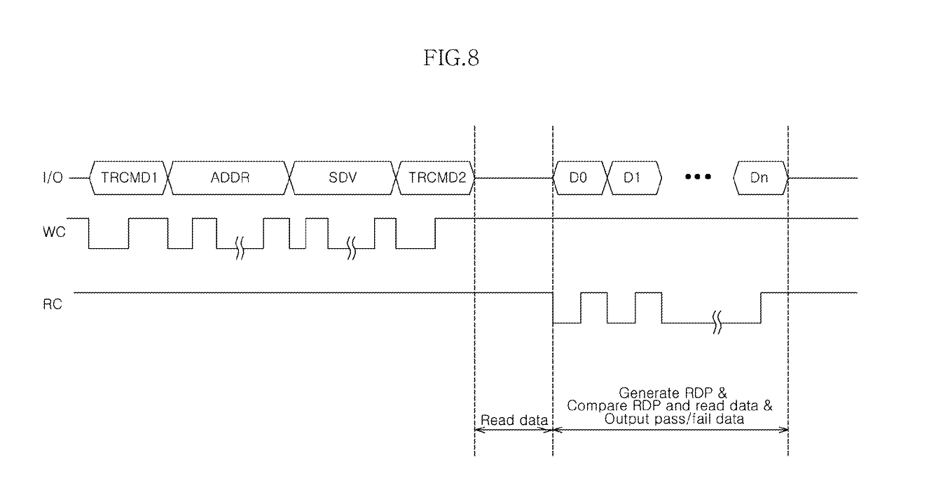

FIG. 8 is a timing diagram illustrating the first test read method of FIG. 6. FIG. 8 depicts a timing diagram of input/output data and control signals based on the flow chart of the first test read method.

The first test read command TRCMD1, the address ADDR, the seed SDV, and the second test read command TRCMD2 are provided to the semiconductor memory device in synchronization with the write control signal WC. FIG. 8 illustrates that the signals TRCMD1, ADDR, SDV, and TRCMD2 are sequentially provided. However, the sequence may be changed. Meanwhile, the size of the seed value SDV may differ depending on the complexity of the random data pattern RDP.

When the second test read command TRCMD2 is provided, data programmed in memory cells are read. That is, after the second test read command TRCMD2 is provided, the data of the memory cell array 110 are read by the data read/write circuit 140 of FIG. 7.

The generation of the random data pattern RDP, the comparison between the random data pattern RDP and the read data, and the output operation of the comparison result are performed in response to the read control signal RC. For example, the random data pattern generator 171 of FIG. 7 generates the random data pattern RDP in response to a clock signal CLK1_R generated based on the read control signal RC. Furthermore, the data read/write circuit 140 provides the read data to the comparator 173 of FIG. 7 in response to the read control signal RC. Furthermore, the comparator 173 compares the random data pattern RDP to the read data in response to the clock signal CLK2_R generated based on the read control signal RC, and outputs the comparison result (that is, pass/fail data). Although not illustrated, the comparison result outputted from the comparator 173 is outputted to the external device, for example, the test device through the input/output buffer circuit 150 of FIG. 1.

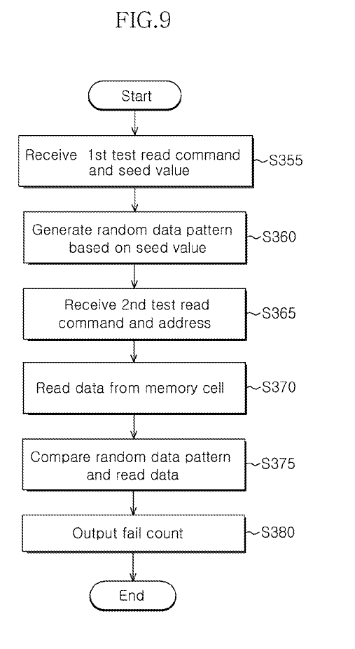

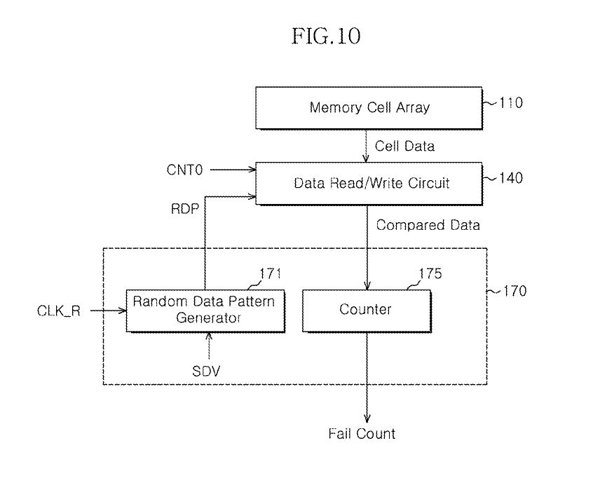

FIG. 9 is a flow chart showing a second test read method of the test method of FIG. 2 in more detail. FIG. 10 is a block diagram of the semiconductor memory device according to an embodiment of the present invention. Hereafter, referring to FIGS. 9 and 10, the second test read method according to an embodiment of the present invention will be described in detail.

At step S355, the semiconductor memory device 100 of FIG. 1 receives a first test read command and a seed value SDV from an external device, for example, a test device. The received seed value SDV is provided to the random data pattern generator 171 of the random data pattern test unit 170.

At step S360, the random data pattern generator 171 generates a random data pattern RDP based on the seed value SDV. The random data pattern generator 171 may generate the random data pattern RDP in response to a clock signal CLK_R provided from the control logic 160 of FIG. 1. The clock signal CLK_R may be generated based on a read control signal RC. For this reason, the number of generated random data patterns RDP corresponds to the toggling number of the read control signal RC. The random data pattern generator 171 provides the random data pattern RDP to the data read/write circuit 140. The random data pattern RDP may be temporarily stored in the data read/write circuit 140.

At step S365, the semiconductor memory device 100 receives a second test read command and an address from the external device, for example, the test device. At step S370, after the second test read command is received, the data read/write circuit 140 reads cell data from memory cells of the memory cell array 110. That is, the data read/write circuit 140 reads the data programmed in the memory cells. The read data may be temporarily stored in the data read/write circuit 140.

At step S375, the data read/write circuit 140 compares the temporarily-stored random data pattern RDP to the read data according to a control signal CNT0 provided from the control logic 160, and provides the compared data, that is, the comparison result to a counter 175. For example, the data read/write circuit 140 outputs test pass data to the counter 175, when the random data pattern RDP and the read data have the same value. Furthermore, the data read/write circuit 140 may output test fail data to the counter 175 when the random data pattern RDP and the read data have different values.

At step S380, the counter 175 counts the number of fail data based on the compared data provided from the data read/write circuit 140. The counter 175 may output the number of fail data to the external device, for example, the test device according to the control of the control logic 160. The counter 175 may be included in the control logic 160, and may be physically separated from the control logic 160.

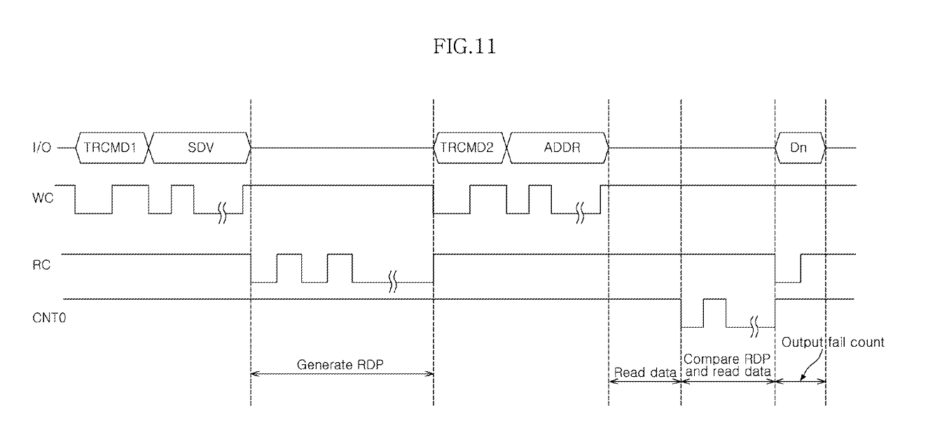

FIG. 11 is a timing diagram illustrating the second test read method of FIG. 9. FIG. 11 depicts a timing diagram of input/output data and control signals based on the flow chart of the second test read method of FIG. 9.

The first test read command TRCMD1 and the seed value SDV are provided to the semiconductor memory device in synchronization with the write control signal WC. The size of the seed value SDV may differ depending on the complexity of the random data pattern RDP.

After the seed value SDV is provided, the random data pattern RDP is generated in response to the read control signal RC. For example, the random data pattern generator 171 of FIG. 10 generates the random data pattern RDP in response to the clock signal CLK_R generated based on the read control signal RC.

When the second test read command TRCMD2 and the address are provided, data programmed in memory cells are read. That is, after the second test read command TRCMD2 is provided, the data read/write circuit 140 of FIG. 10 reads the data of the memory cell array 110. The data read/write circuit 140 compares the stored random data pattern to the read data in response to the control signal CNT0, and outputs the comparison result to the counter 175.

Depending on the necessity, the number of fail data may be outputted in response to the read control signal RC provided from the external device, for example, the test device. As another example, the number of fail data may be outputted according to a state check command provided from the external device, for example, the test device. The number of fail data may be temporarily stored in the control logic 160 or the counter 175 until the value is outputted to the external device.

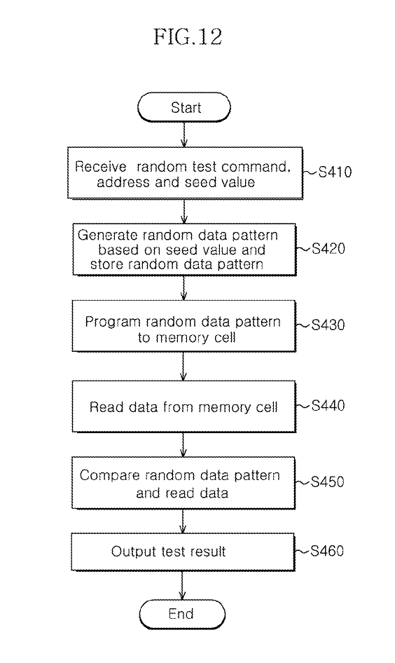

FIG. 12 is a flow chart showing a test method of a semiconductor memory device according to another embodiment of the present invention. Referring to FIG. 12, the test method of the semiconductor memory device 100 of FIG. 1 is characterized in that operations of generating a random data pattern, programming the generated random data pattern, reading data from memory cells, and comparing the generated random data pattern to the read data are sequentially performed according to one command, for example, random test command. Hereafter, the test method of the semiconductor memory apparatus will be described in detail with reference to FIGS. 1 and 12.

At step S410, the semiconductor memory device 100 receives a random test command, an address, and a seed value from an external device, for example, a test device.

At step S420, the random data pattern test unit 170 of the semiconductor memory device 100 generates a random data pattern based on the received seed value. This means that data to be used for a test program operation are not provided from the external device, for example, the test device. The generated random data pattern is temporarily stored until a subsequent comparison operation is performed. For example, the random data pattern provided to the data read/write circuit 140 of FIG. 1 from the random data pattern test unit 170 may be temporarily stored in a latch circuit of the data read/write circuit 140, while a program operation and a subsequent comparison operation are performed.

At step S430, the data read/write circuit 140 programs the received random data pattern to memory cells. At step S440, the data read/write circuit 140 reads the data programmed in the memory cells. For example, the data read/write circuit 140 may temporarily store the read data in the latch circuit.

At step S450, the data read/write circuit 140 compares the stored random data pattern to the stored read data according to the control of the control logic 160, and stores the comparison result. For example, the data read/write circuit 140 stores test pass data in the corresponding latch circuit, when the random data pattern and the read data have the same value. Furthermore, the data read/write circuit 140 stores test fail data in the corresponding latch circuit, when the random data pattern and the read data have different values.

At step S460, the semiconductor memory device 100 outputs the test result stored in the data read/write circuit 140 to the external device, for example, the test device.

As the series of operations are sequentially performed, it is possible to test whether or not the semiconductor memory device 100 stably operates with respect to the random data pattern.

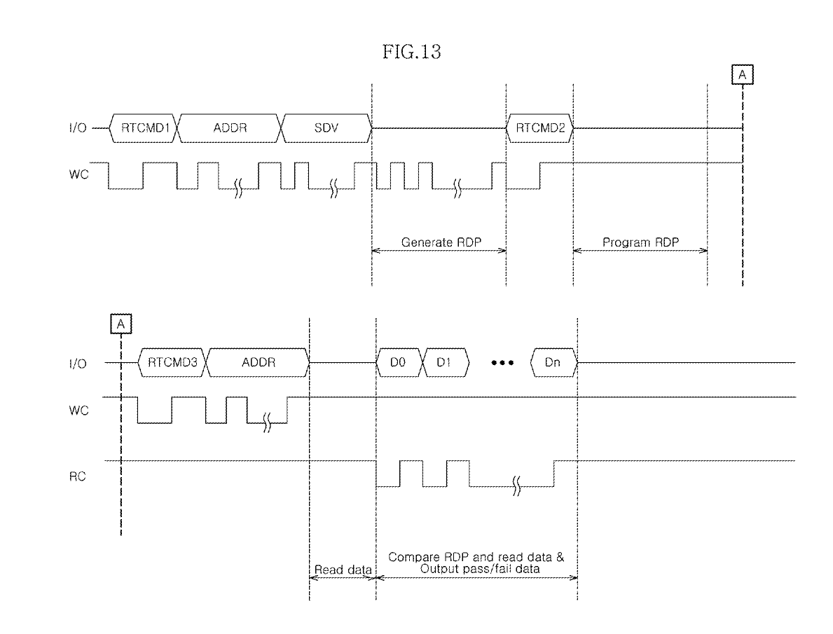

FIG. 13 is a timing diagram illustrating a test method of a semiconductor memory device according to yet another embodiment of the present invention.

The first random test command RTCMD1, the address ADDR, and the seed value SDV are provided to the semiconductor memory device in synchronization with the write control signal WC. The size of the seed value SDV may differ depending on the complexity of the random data pattern RDP. The random data pattern RDP is generated in response to the write control signal WC.

When the second random test command RTCMD2 is successively provided, the generated random data pattern RDP is programmed into memory cells. That is, after the second random test command RTCMD2 is provided, an actual program operation to apply a program current or voltage is performed.

When the third random test command RTCMD3 and the address ADDR are successively provided, the data programmed in the memory cells are read. Furthermore, the temporarily-stored random data pattern and the read data are compared to each other. Furthermore, the comparison result is outputted to the external device. The read operation, the comparison operation, and the output operation of the comparison result may be performed in response to the read control signal RC.

According to the embodiments of the present invention, the semiconductor memory device 100 is configured to internally perform is a test operation for a random data pattern. Therefore, the test time may be reduced more than when a test is performed under control of an external device. Furthermore, since the external device does not need to manage the random data pattern, the test cost may be reduced more than when a test is performed under control of the external device.

While certain embodiments have been described above, it will be understood to those skilled in the art that the embodiments described are by way of example only. Accordingly, the semiconductor memory device and the test method described herein should not be limited based on the described embodiments. Rather, the semiconductor memory device and the test method described herein should only be limited in light of the claims that follow when taken in conjunction with the above description and accompanying drawings.

What is claimed is:

1. A test method of a semiconductor memory device, comprising the steps of:
generating a first random data pattern inside the semiconductor memory device and programming the first random data pattern into the semiconductor memory device; and
generating a second random data pattern inside the semiconductor memory device and comparing the second random data pattern to a data pattern read from memory cells of the semiconductor memory device.

2. The test method according to claim 1, wherein the step of generating the first random data pattern inside the semiconductor memory device and programming the first random data pattern into the semiconductor memory device comprises the steps of:
receiving a seed value from an external device; and
generating the first random data pattern based on the received seed value.

3. The test method according to claim 2, wherein the seed value is received at least one time depending on complexity of the first random data pattern.

4. The test method according to claim 3, wherein the first and second random data patterns are generated based on the same seed value.

5. The test method according to claim 2, wherein the step of generating the first random data pattern inside the semiconductor memory device and programming the first random data pattern into the semiconductor memory device further comprises the steps of:
receiving a test program command; and
receiving an addresses of a memory cell into which the first random data pattern is to be programmed.

6. The test method according to claim 5, wherein the step of receiving the test program command, the step of receiving the address of the memory cell, the step of generating the first random data pattern, and the step of programming the first random data pattern are sequentially performed.

7. The test method according to claim 1, wherein the step of generating the second random data pattern inside the semiconductor memory device and comparing the second random data pattern to the data pattern read from the memory cells of the semiconductor memory device comprises the steps of:
receiving a seed value from an external device; and
generating the second random data pattern based on the received seed value.

8. The test method according to claim 7, wherein the step of generating the second random data pattern inside the semiconductor memory device and comparing the second random data pattern to the data pattern read from the memory cells of the semiconductor memory device further comprises the steps of:
receiving a test read command;
receiving an address for reading the memory cells; and
reading the memory cells.

9. The test method according to claim 8, wherein the step of receiving the test read command, the step of receiving the address, the step of receiving the seed value, the step of reading the memory cells, and the step of generating the second random data pattern are sequentially performed.

10. The test method according to claim 8, wherein the step of receiving the test read command, the step of receiving the address, and the step of receiving the seed value are sequentially performed, and
the step of generating the second random data pattern and the step of reading the memory cells are performed at the same time.

11. The test method according to claim 8, wherein the test read command is divided into a first test read command and a second test read command, and
the step of generating the second random data pattern is performed between the step of receiving the first test read command and the step of receiving the second test read command.

12. The test method according to claim 11, wherein the step of reading the memory cells is performed after the second test read command is received.

13. The test method according to claim 12, further comprising the step of outputting a comparison result including the number of fail is data.

14. A test method of a semiconductor memory device, comprising the steps of:
generating a random data pattern inside the semiconductor memory device in response to a test command provided from an external device;
performing a test using the random data pattern; and
outputting a test result to the external device.

15. The test method according to claim 14, wherein the random data pattern is generated based on a seed value provided from an external device.

16. The test method according to claim 14, wherein the random data pattern is programmed into memory cells of the semiconductor memory device, and the random data pattern and the data read from the memory cells are compared.

17. The test method according to claim 14, wherein the test result comprises the number of fail data.

18. The test method according to claim 14, wherein the test result comprises test pass/fail information on each of memory cells of the semiconductor memory device.

19. A semiconductor memory device comprising:
memory cells;
a random data pattern test unit configured to generate a random data pattern; and
a data read/write circuit configured to program the random data pattern provided from the random data pattern test unit into the memory cells during a test operation.

20. The semiconductor memory device according to claim 19, wherein the random data pattern test unit generates the random data pattern based on a seed value provided from an external device.

21. The semiconductor memory device according to claim 20, wherein the random data pattern test unit generates the random data pattern in response to a write control signal provided from the external device.

22. The semiconductor memory device according to claim 21, wherein the size of the random data pattern is decided according to the toggling number of the write control signal.

23. The semiconductor memory device according to claim 19, wherein the random data pattern test unit comprises a comparator.

24. The semiconductor memory device according to claim 23, wherein the data read/write circuit reads the data programmed in the memory cells, and provides the read data to the comparator, and
the comparator compares the random data pattern to the read data, and outputs a comparison result.

25. The semiconductor memory device according to claim 24, wherein the comparator performs the comparison and output operations in response to a read control signal provided from an external device.

26. The semiconductor memory device according to claim 19, wherein the random data pattern test unit comprises a counter.

27. The semiconductor memory device according to claim 26, wherein the data read/write circuit reads the data programmed in the memory cells, compares the random data pattern to the read data, and provides a comparison result to the counter, and
the counter counts the number of fail data by referring to the comparison result, and outputs the counted number of fail data.

28. The semiconductor memory device according to claim 27, wherein the data read/write circuit temporarily stores the random data pattern provided from the random data pattern test unit.

29. The semiconductor memory device according to claim 19, further comprising a control logic configured to control the random data pattern test unit and the data read/write circuit in response to a test command provided from an external device.

30. The semiconductor memory device according to claim 19, wherein the random data pattern test unit comprises a linear feedback shift register (LFSR).
